(19) United States
(12) Patent Application Publication
(10) Pub. No.: US 2008/0144264 A1
(43) Pub. Date: Jun. 19, 2008

(54) THREE PART HOUSING WIRELESS COMMUNICATIONS DEVICE

(75) Inventor: Steven John Cosgrove, Singapore (SG)

Correspondence Address: MOTOROLA INC, 600 NORTH US HIGHWAY 45, W4 - 39Q, LIBERTYVILLE, IL, 60048-5343, US

(73) Assignee: MOTOROLA, INC., LIBERTYVILLE, IL (US)

(21) Appl. No.: 11/610,523

(22) Filed: Dec. 14, 2006

(51) Int. Cl. H05K 7/00

(52) U.S. Cl. 361/681

(57) ABSTRACT

A three part housing wireless communications device (100) with a display housing portion (110) with a display screen (137) and a left ear housing portion (160), with a with a left speaker 161 and left ear mount 340, pivotally mounted to the display housing portion (110). There is a right ear housing portion (170), with a right ear mount (440) and a right speaker 171, pivotally mounted to the display housing portion (110). The three part housing wireless communications device (100) has a radio frequency communications unit mounted providing wireless communication with a communications network.

### FIELD OF THE INVENTION

This invention relates in general to a three part housing wireless communications device. The invention is particularly useful for, but not necessarily limited to, a multi speaker three part housing wireless communications device with multimedia entertainment capabilities.

### BACKGROUND OF THE INVENTION

Portable communications devices such as cellular telephones are becoming commonplace in society. With increasing use of such devices there has been a demand for increased functionality and greater compactness for ease and convenience of use. Customarily, these portable communications devices accompany users most of the time and recently there has been a trend towards providing multimedia entertainment capabilities including music playing features and video content playing features on such devices. These multimedia entertainment capabilities may allow for multimedia content to be transmitted to the device remotely, for instance by Frequency Modulated (FM) radio or video streaming. Alternatively, the multimedia content may be stored in permanent memory on the device typically in MPEG, MP3 or any other suitable format.

When playing or displaying multimedia content including visual content such as picture, streaming television, video content, webcasts and the like, a user may not be able to view or listen to the content without being distracted by ambient conditions. For instance, when in a public place visual and audible distractions including, human traffic, vehicular traffic and bright or flashing lights may irritate, annoy and distract the user whilst viewing the content or listening to the content.

### BRIEF DESCRIPTION OF THE DRAWINGS

In order that the invention may be readily understood and put into practical effect, reference will now be made to exemplary embodiments as illustrated with reference to the accompanying figures, where like reference numerals refer to identical or functionally similar elements throughout the separate views. The figures together with a detailed description below, are incorporated in and form part of the specification, and serve to further illustrate the embodiments and explain various principles and advantages, in accordance with the present invention where:

FIG. 1 is a schematic block diagram of a three part housing wireless communications device in accordance with a first embodiment of the invention;

FIG. 2 is a perspective view of an embodiment of the three part housing wireless communications device of FIG. 1 with left and right ear housing portions being in a closed position;

FIG. 3 is a perspective view of the housing portions of three part housing wireless communications device of FIG. 1 having the left ear housing portion in an opened position;

FIG. 4 is a perspective view of the housing portions of three part housing wireless communications device of FIG. 1 having the right ear housing portion in the opened position;

FIG. 5 is a perspective view of the three part housing wireless communications device of FIG. 1 having the left and right ear housing portions in the opened position;

FIG. 6 illustrates the three part housing wireless communications device of FIG. 1 when worn by a user;

FIG. 7 illustrates a second embodiment of part of the right ear housing portion;

FIG. 8 illustrates a third embodiment of part of the right ear housing portion;

FIG. 9 is a perspective view of another embodiment of the three part housing wireless communications device with the left and right ear housing portions being in an opened position and retractable visors in a retracted position;

FIG. 10 is a perspective view of a second embodiment of the three part housing wireless communications device of FIG. 9 with the retractable visors in an extended position; and

FIG. 11 illustrates the three part housing wireless communications device of FIG. 9 when worn by a user.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of components related to a three part housing wireless communications device. Accordingly, the device components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,”0 “comprising,” or any other variation thereof, are intended to cover a non-exclusive inclusion, such that a device that comprises a list of elements does not include only those elements but may include other elements not expressly listed or inherent to such a device.

It will be appreciated that embodiments of the invention described herein may be comprised of one or more conventional processors and unique stored program instructions that control the one or more processors to implement, in conjunction with certain non-processor circuits, some, most, or all of the functions of the a three part housing wireless communications device described herein. The non-processor circuits may include, but are not limited to, a radio receiver, a radio transmitter, signal drivers, clock circuits, power source circuits, and user input devices. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

According to one aspect of the invention there is provided three part housing wireless communications device comprising a display housing portion that houses at least one display screen. There is a left ear housing portion pivotally mounted to the display housing portion, with a left speaker mounted therein. There is a left ear mount protruding from the left ear housing portion, the left ear mount being proximal to the left ear speaker, and the left ear mount being shaped to mount the left ear housing portion to a left ear of a user. The three part housing wireless communications device also has a right ear housing portion pivotally mounted to the display housing portion, the right ear housing portion having a right speaker mounted therein. Further, there is a right ear mount protruding from the right ear housing portion, the right ear mount being proximal to the right speaker, the right ear mount being shaped to mount the right ear housing portion to a right ear of the user, wherein the three part housing wireless communications device has a radio frequency communications unit mounted therein, the radio frequency communications unit providing wireless communication with a communications network.

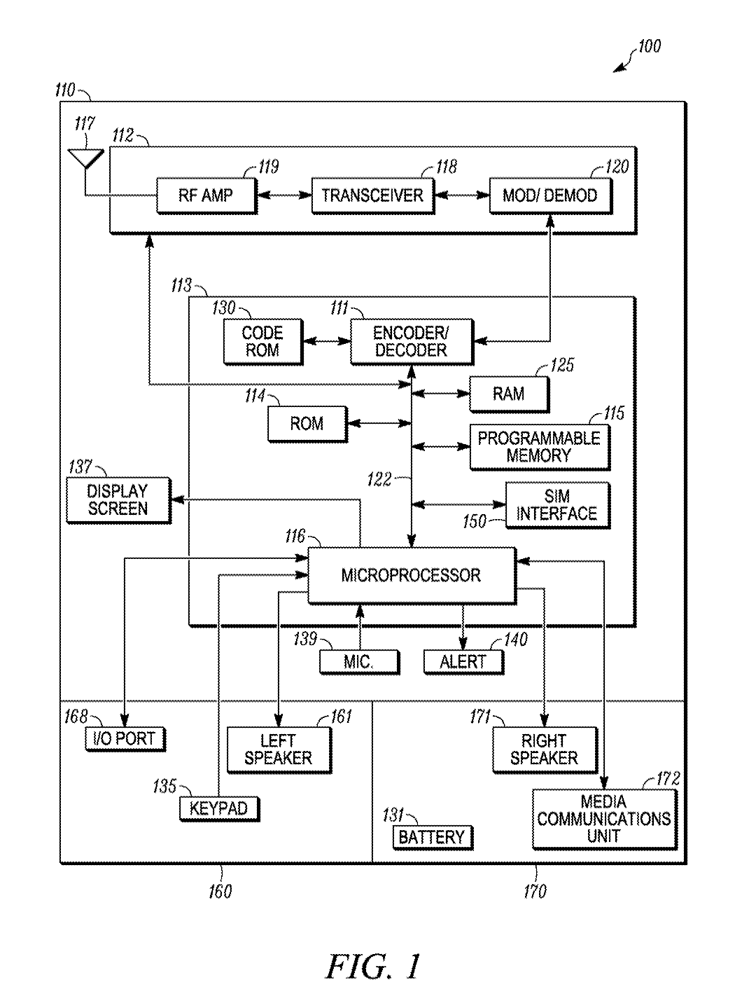

In the drawings, like numerals on different Figs are used to indicate like elements throughout. With reference to FIG. 1, there is illustrated a schematic block diagram of a first embodiment of a three part housing wireless communications device 100. The three part housing wireless communications device 100 comprises a display housing portion 110 that houses, amongst other components and units, a display screen 137 typically in the form of a Liquid Crystal Display (LCD), a left ear housing portion 160 and a right ear housing portion 160. Housed in or associated with the display housing portion 110 is a radio frequency communications unit 112 providing wireless communication with a telephone network as will be apparent to a person skilled in the art. Also housed or mounted in the display housing portion 110 is a processor 113 that includes an encoder/decoder 111 with an associated Code Read Only Memory (ROM) 130 storing data for encoding and decoding voice, music or other signals that may be transmitted or received by the radio frequency communications unit 112. The processor 113 also includes a micro-processor 116 operatively coupled, by a common address, control and data bus 122, to the primary encoder/decoder 111, a Read Only Memory (ROM) 114 and a Random Access Memory (RAM) 125, a programmable memory 115 and a Subscriber Identity Module (SIM) interface 150. The programmable memory 115 and a SIM operatively coupled to the SIM interface 150 each can store, among other things, selected text messages and a Telephone Number Database (TND) comprising a number field for telephone numbers and a name field for identifiers associated with one of the numbers in the name field.

The Read only memory (ROM) 114 stores multi-media content (including music) and operating code (OC) for micro-processor 116 to run the basic functions associated with the three part housing wireless communications device 100. The radio frequency communications unit 112 is a combined receiver and transmitter having a common antenna 117. The radio frequency communications unit 112 has a transceiver 118 coupled to the common antenna 117 via a radio frequency amplifier 119. The transceiver 118 is also coupled to a combined primary modulator/demodulator 120 that couples the radio frequency communications unit 112 to the encoder/decoder 111 of the processor 113. Also, the radio frequency communications unit 112 is coupled to the microprocessor by the common address, control and data bus 122.

A microphone 139 and an alert signal generator 140 are also mounted in or on the display housing portion 110. Both the microphone 139 and the alert signal generator 140 are coupled to ports of the micro-processor 116.

Mounted in or on the left ear housing portion 160 are a keypad 135, a left speaker 161 and an Input/Output port 168. The keypad 135, the left speaker 161 and the Input/Output port 168 are coupled to ports of the micro-processor 116 to allow operative coupling of media content hardware and gaming hardware to the microprocessor 116.

Mounted in or on the right ear housing portion 170 are a right speaker 171, a media communications unit 172 and battery compartment 131 for storing battery cells for providing power to the to the aforementioned circuitry and components. The power lines from the battery compartment 131 are not shown but will be apparent to a person skilled in the art. The media communications unit 172 may include radio receiver, internet ports, media buffering, media storage and media playing software and hardware.

As will be apparent to a person skilled in the art, the left speaker 161 and right speaker 171 may include more than just an electric signal to sound transducer. The speakers 161 and 171 may each include a power amplifier and digital to analogue converter. Alternatively, respective output ports of microprocessor 116 may include a power amplifier and digital to analogue converter.

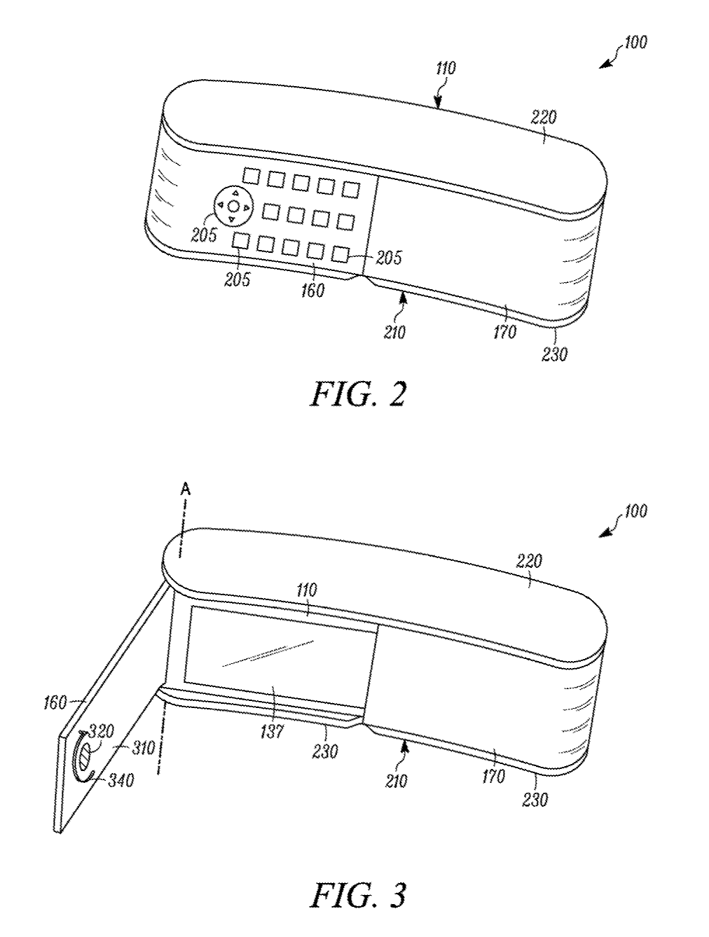

Referring to FIG. 2 there is illustrated a perspective view of the three part housing wireless communications device 100 with the left and right ear housing portions 160,170 being in a closed position. As illustrated, keys 205 of the keypad 135 are on an outer side of the left ear housing portion 160 and there is an upper visor 220 and lower visor 230 extending from the display housing portion 110 and when in the closed position illustrated, the upper visor 220 and lower visor 230 partially enclose the left and right ear housing portions 160,170. There is also a microphone aperture 210 on an underside of the lower visor 230, the microphone aperture 210 being aligned with the microphone 139 that is mounted adjacent a lower edge of the display housing 110 as will be apparent to a person skilled in the art.

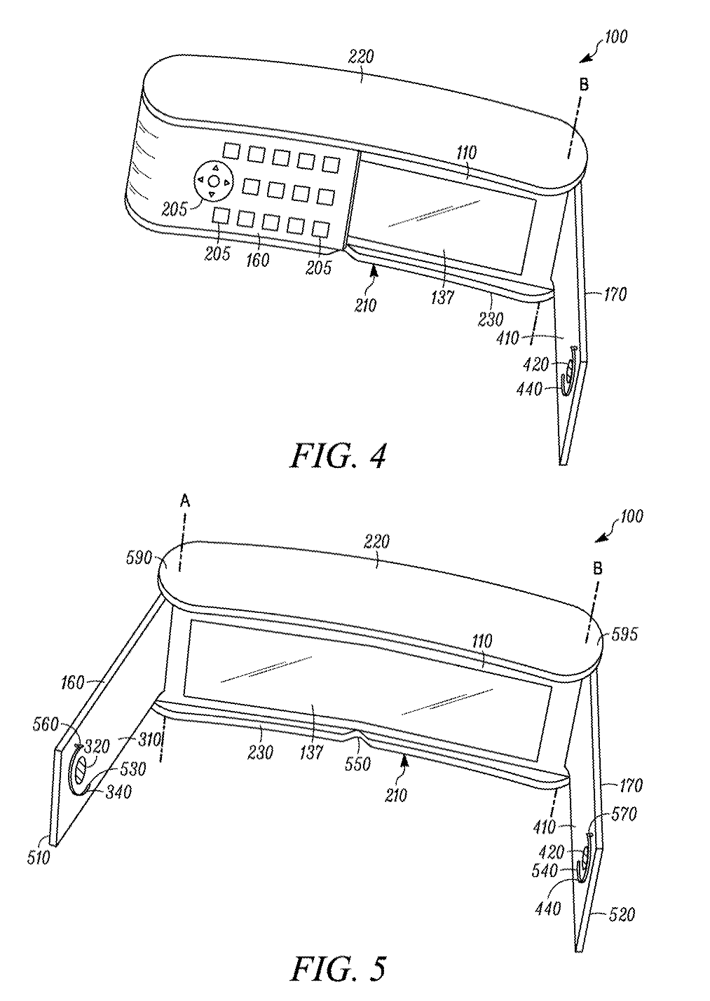

Referring to FIG. 3 there is illustrated a perspective view of the housing portions of three part housing wireless communications device 100 with the left ear housing portion 160 in an opened position. The left ear housing portion 160 is pivotally mounted to the display housing portion 110 about a pivotal axis A to allow the left ear housing portion 160 to move from a closed position (as shown in FIG. 2 or FIG. 4) to the opened position.

The left ear housing potion 160 has the left speaker 161 mounted therein at a position aligned directly underneath a left speaker grille 320 located in a left ear housing portion inner face 310, the left speaker grille 320 comprising at least one aperture in the left ear housing portion inner face 310. There is also a left ear mount 340 protruding from the left ear housing portion 160, the left ear mount 340 being proximal to the left speaker 161 and the left speaker grille 320. Further, the left ear mount 340 is shaped to mount the left ear housing portion 160 to a left ear of a user.

As illustrated, with the left ear housing portion 160 in the opened position and the right ear housing portion 170 in the closed position, half of the display screen 137 is visible.

Referring to FIG. 4 there is illustrated a perspective view of the housing portions of three part housing wireless communications device 100 with the right ear housing portion 170 in an opened position. The right ear housing portion 170 is pivotally mounted to the display housing portion 110 about a pivotal axis B to allow the right ear housing portion 170 to move from a closed position (as shown in FIG. 2 or FIG. 3) to the opened position.

The right ear housing potion 170 has the right speaker 171 mounted therein at a position aligned directly underneath a right speaker grille 420 located in a right ear housing portion inner face 410, the right speaker grille 420 comprising at least one aperture in the right ear housing portion inner face 410. There is also a right ear mount 440 protruding from the right ear housing portion 170, the right ear mount 440 being proximal to the right speaker 171 and the right speaker grille 420. Further, the right ear mount 440 is shaped to mount the right ear housing portion 170 to a right ear of a user.

As illustrated, with the right ear housing portion 170 in the opened position and the left ear housing portion 160 in the closed position, half of the display screen 137 is visible. Hence, a user can dial a telephone number or input commands or functions using the keys 205 whilst observing feedback information, indicia or instructions on visible part of the display screen 137. Further, the user can answer a call or dial a number and communicate with a telephone in a conventional manner using the right speaker 171 and microphone 139.

Referring to FIG. 5 there is illustrated a perspective view of the three part housing wireless communications device 100 with the left and right ear housing portions 160,170 in an opened position. As illustrated, the left ear mount 340 and right ear mount 440 are located adjacent respective free ends 510,520 of the left ear housing portion 160 and right ear housing portion 170. More specifically, the right ear housing portion 170 and the left ear housing portion 160 are pivotally mounted at opposite ends 595,590 of the display housing portion 110. Also, the left ear mount 340 and right ear mount 440 are ear hooks each formed from flexible plastics material having a respective ear hook free end 530,540 and an opposite fixed ends 560,570 that mount the left and right ear mounts 340,440 to the respective left and right ear housing portions 160,170. Also, illustrated in this opened position, the upper and lower visor portions extend from the display housing portion 110 and form brims that partially enclose the display screen 137. There is also a recess 550 in the lower visor portion 230 for accommodating a nose bridge of a user whilst wearing the three part housing wireless communications device 100.

From the above Figs. it is clear that the left ear housing portion 160 and right ear housing portion 170 are both movable relative to the display housing portion, about respective axes A,B from an opened position to a closed position thereby covering the display screen 137 when in the closed position and when in the opened position the display screen is uncovered.

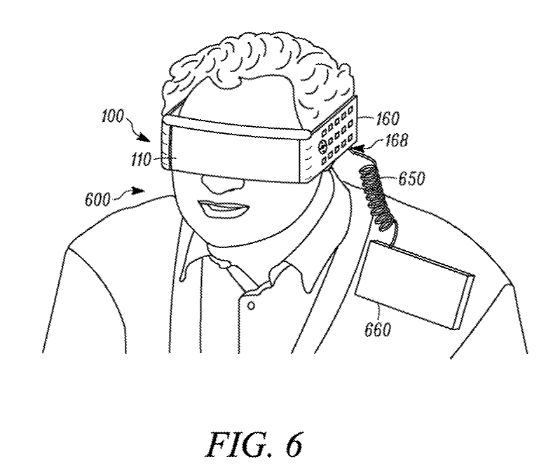

In FIG. 6, there is illustrated the three part housing wireless communications device 100 when worn by a user 600. When worn by the user 600, the left and right ear mounts 340, 440 hook onto respective left and right ears of the user 600. The recess 550 also accommodates the nose of the user. Thus, the three part housing wireless communications device 100 can be readily worn by the user 600 in a manner similar to that of wearing glasses. As shown, there is a gaming hardware device 640 coupled by a cable 650 to Input/Output port 168 thus the user 600 can enjoy gaming or media content supplied by the gaming hardware device, or by media content stored or received by the media communications unit 172 or stored in the programmable memory 115. It is envisaged that when the device 100 is worn, the user 600 can answer an incoming telephone call, or initiate a telephone call, by actuation of the required keys 205 on the keypad 135 (or a call can be automatically answered upon receipt thereof) and media content can be automatically place on pause or disabled for the duration of the call. The user can continue to wear the device 100 during the call in which the microphone 139 is located conveniently near the user's mouth and the left speaker 161 and right speaker 171 are located adjacent the ears of the user 600 and are used for emitting audio signals received during the call.

It will therefore be apparent to a person skilled in the art that media content including stereophonic music, video content, teleconferencing, relaxing music accompanied by patterns and colors on the display screen 137 can be enjoyed without visual ambient distractions. The user can adjust the volume and content being played by actuating the required keys on the keypad 135. Audio media content can be enjoyed in stereo through the left and right ear speakers 161,171. The user can also participated in video conferencing using the device 100 without being unnecessarily distracted by ambient noise and visual disturbances as the visors combined with then left and right ear housing portions provide visual sensory ambient isolation whilst the speakers placed next to the ear's of the user in combination with the left and right ear housing portions provide audio sensory ambient isolation.

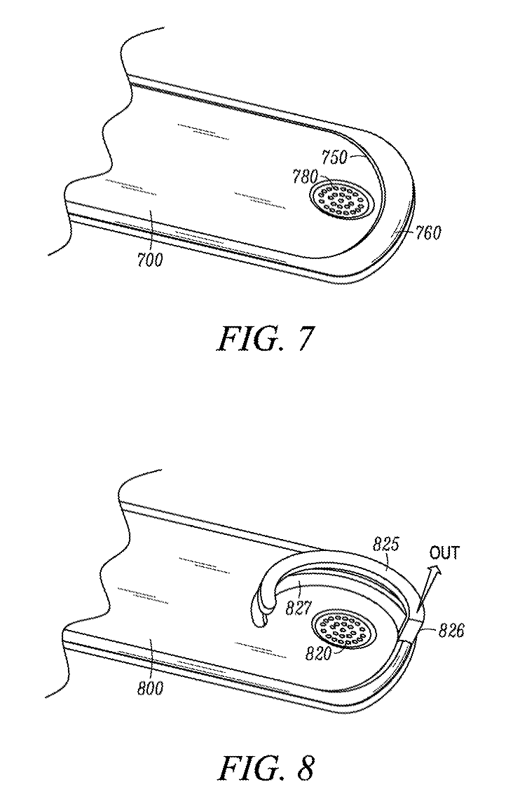

In FIG. 7 there is illustrated a second embodiment of part of a right ear housing portion 700. It will be understood that, although not specifically illustrated, there is also a similar left ear hosing portion. The right ear housing portion 700 has a right ear mount that is a shouldered rim 750 located at a free end 760 of the right ear housing portion 700, the shouldered rim 750 typically being integrally moulded with the right ear housing portion 700. Also, the shouldered rim is proximal to the right speaker 171 that has an adjacent aligned associated grille 780 comprising at least one aperture in the right ear housing portion 700.

Referring to FIG. 8 there is illustrated a third embodiment of part of a right ear housing portion 800. It will be understood that, although not specifically illustrated, there is also a similar left ear housing portion. The right ear mount is in the form of an ear hook 825 slidably mounted (attached) to the right ear housing portion 800. The ear hook 825 is proximal to the right speaker 171 that has an adjacent aligned associated grille 820 comprising at least one aperture in the right ear housing portion 800. As shown, the ear hook 825 partially surrounds the grille 820. The ear hook 825 is locatable in a complementary shaped recess 827 and is movable out of the recess 827 in a direction illustrated by arrowed line OUT by a user pulling on a lateral shoulder 826 of the ear hook 825. The ear hook 825 can be inserted back into the recess 827 by simply pushing on its outer surface in a direction opposite to that of the arrowed line OUT.

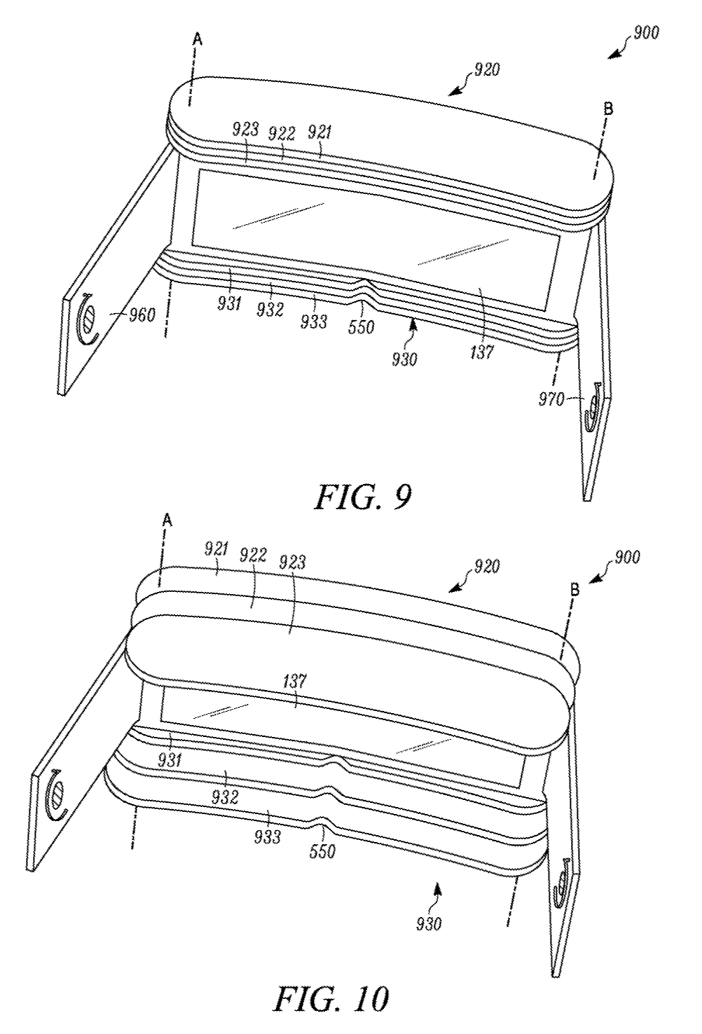

Referring to FIG. 9 there is illustrated a perspective view of another embodiment of a three part housing wireless communications device 900 with the left and right ear housing portions 960,970 being in an opened position and retractable visors 920,930 being in a retracted position. The retractable visor 920 comprises three members 921,922,923, assembled and configured to slide from the retracted position of FIG. 9 to an extended position of FIG. 10. Also, the retractable visor 930 comprises three members 931,932,933, assembled and configured to slide from the retracted position of FIG. 9 to an extended position of FIG. 10.

The assembly of the members 921,922,923 is achieved using any conventional retractable assembly arrangements such as snap fitted spigots engaging slotted tracks as will be apparent to a person skilled in the art. As similar assembly is used for the members 931,932, 33 and when in the retracted position respective apertures in each of the members 931,932,933 are aligned with the microphone 139. When in the extended position, the members 932,933 clear the aperture in the member 931 so as not to obstruct or impede the microphone 139 from receiving speech signals from a user.

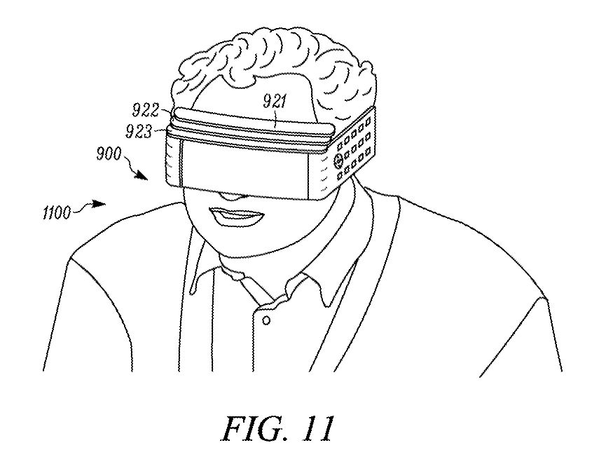

Referring to FIG. 11 there is illustrated the three part housing wireless communications device 900 when worn by a user 1100 when both visors 920,930 are in the extended position. Advantageously, when in the extended position, the visors 920,930 provide a spacing that typically spaces the display screen 137 at a distance of 10 cm to 12 cm from the user's 1100 eyes, this distance is typically within the range of a human eye's minimal focal length. Thus alphanumeric text, characters and high resolution indicia can be readily viewed by the user when wearing the device 900. Also, the embodiment of three part housing wireless communications device 900 can be used and has the same advantages as embodiment of the three part housing wireless communications device 900.

In the foregoing specification, specific embodiments of the present invention have been described. However, one of ordinary skill in the art appreciates that various modifications and changes can be made without departing from the scope of the present invention as set forth in the claims below. For example, although a flip or clamshell device is shown the device could also be a two piece candy-bar device that dose not have two portions pivotally mounted to each other but instead the portions when mounted are in a fixed opened position. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims.

We claim:

1. A three part housing wireless communications device comprising:
a display housing portion that houses at least one display screen;
a left ear housing portion pivotally mounted to the display housing portion, with a left speaker mounted therein,
a left ear mount protruding from the left ear housing portion, the left ear mount being proximal to the left ear speaker, and the left ear mount being shaped to mount the left ear housing portion to a left ear of a user;
a right ear housing portion pivotally mounted to the display housing portion, the right ear housing portion having a right speaker mounted therein; and
a right ear mount protruding from the right ear housing portion, the right ear mount being proximal to the right speaker, and the right ear mount being shaped to mount the right ear housing portion to a right ear of the user, wherein the three part housing wireless communications device has a radio frequency communications unit mounted therein, the radio frequency communications unit providing wireless communication with a communications network.

2. A three part housing wireless communications device as claimed in claim 1, wherein the left ear mount and right ear mount are located adjacent respective free ends of the left ear housing portion and right ear housing portion.

3. A three housing part wireless communications device as claimed in claim 2, wherein the right ear mount is a shouldered rim.

4. A three part housing wireless communications device as claimed in claim 1, wherein right ear mount is an ear hook.

5. A three part housing wireless communications device claimed in claim 4, wherein the right ear mount is locatable in a complementary shaped recess in the right ear housing portion.

6. A three part housing wireless communications device claimed in claim 1, wherein the right ear housing portion and the left ear housing portion are pivotally mounted at opposite ends of the display housing portion.

7. A three part housing wireless communications device as claimed in claim 1, wherein the radio frequency communications unit provides wireless communication with a communications network.

8. A three part housing wireless communications device as claimed in claim 1, wherein the microphone is mounted adjacent a lower edge of the display housing.

9. A three part housing wireless communications device as claimed in claim 1, wherein the left ear housing portion and right ear housing portion are both movable relative to the display housing portion from an opened position to a closed position thereby covering the display screen when in the closed position and when in the opened position the display screen is uncovered.

10. A three part housing wireless communications device as claimed in claim 1, wherein there are upper and lower visors extending from a the display housing portion, and wherein the upper and lower visors partially enclose the display screen.

11. A three part housing wireless communications device as claimed in claim 10, wherein when in the closed position the upper and lower visors partially enclose the left ear housing portion and right ear housing portion.

12. A three part housing wireless communications device as claimed in claim 10, wherein there is recess in the lower visor for accommodating a nose bridge of a user whilst wearing the three part housing wireless communications device.

13. A three part housing wireless communications device as claimed in claim 10, wherein the upper and lower visors are retractable.

14. A three part housing wireless communications device as claimed in claim 13, wherein the upper and lower visors are configured to slide from the retracted position of an extended position.
